(19) United States
(12) Patent Application Publication
(10) Pub. No.: US 2006/0245274 A1
(43) Pub. Date: Nov. 2, 2006

(54) Apparatus and method for controlling NAND flash memory

(75) Inventors: Sangik Choi, Yongin-si (KR); Hyang-suk Park, Suwon-si (KR)

Correspondence Address: STEIN, MCEWEN & BUI, LLP, 1400 EYE STREET, NW, SUITE 300, WASHINGTON, DC, 20005, US

(73) Assignee: Samsung Electronics Co., Ltd., Suwon-si (KR)

(21) Appl. No.: 11/256,051

(22) Filed: Oct. 24, 2005

(30) Foreign Application Priority Data
Apr. 30, 2005 (KR) 2005-36528

(51) Int. Cl. G11C 7/00

(52) U.S. Cl. 365/189.12

(57) ABSTRACT

An apparatus and method of controlling data transmission between a NAND flash memory and a central processing unit using a direct memory access (DMA) method. The apparatus includes: a register storing an operating command from the central processing unit and information related to the operating command; a boot memory storing a boot code for initializing a system; a direct memory access (DMA) controller transmitting data stored in the NAND flash memory to a main memory without passing through the central processing unit; and a state machine controlling the NAND flash memory controlling apparatus. Accordingly, data transmission speed is increased, chip memory size is decreased, and booting time is reduced.

### CROSS-REFERENCE TO RELATED APPLICATION

This application claims the benefit of Korean Patent Application No. 10-2005-36528, filed on Apr. 30, 2005 in the Korean Intellectual Property Office, the disclosure of which is incorporated herein in its entirety by reference.

### BACKGROUND OF THE INVENTION

1. Field of the Invention

An aspect of the present invention relates to an apparatus and method of controlling a NAND flash memory, and more particularly, to an apparatus and method of controlling data transmission between a NAND flash memory and a central processing unit (CPU) using a direct memory access (DMA) method.

2. Description of the Related Art

A flash memory is a non-volatile memory device that can retain information stored therein even when a power supply is cut off, and is used as a mass storage device in portable devices such as digital cameras, MP3 players, mobile phones, or USB drivers. Flash memory is divided into NAND flash memory for data storage and NOR flash memory for code storage according to an electronic circuit configuration inside a semiconductor chip.

In a NAND flash memory, since cells, each of which is a storage unit, are vertically arranged, a plurality of cells can be formed in a small area, and the NAND flash memory can be designed to be a mass storage device. Meanwhile, since cells in the NOR flash memory are horizontally arranged, the NOR flash memory has a small capacity, but reading speed is fast, and thus the NOR flash memory can be used in a device such as a mobile phone for storing code data relating to operation of the device. Since, like other memories, the NOR flash memory has an independent address space, an individual address and a data bus, a central processing unit can easily access the NOR flash memory. However, since the NAND flash memory has a common bus for an address and a data bus and does not have an independent address space, control logic is needed to solve the above problems. Furthermore, to use the NAND flash memory for driving a system, that is, booting, a buffer must be included in hardware control logic.

A method of controlling NAND flash memory according to the prior art will be described below with reference to FIG. 1. FIG. 1 is a block diagram schematically illustrating an apparatus for controlling a NAND flash memory 60 according to the prior art.

The NAND flash memory controlling apparatus according to the prior art includes a state machine 10, a boot static random access memory (SRAM) 20, an SRAM buffer 30, a register 40, and an error correction code (ECC) circuit 50, so that the controlling apparatus interfaces with a NAND flash memory 60 through a NAND flash interface, and interfaces with a central processing unit (CPU) 70 and a main memory 80 through a host interface.

The state machine 10 controls operations throughout the NAND flash memory controlling apparatus, and the boot SRAM 20 is a memory for storing a boot code. The register 40 provides a command for driving the state machine 10, and is a storing space for reading a current status. The SRAM buffer 30 acts as a cache interposed between the CPU 70 and the NAND flash memory 60 because the reading/writing speed is different between the CPU 70 and the NAND flash memory 60.

During system booting, a boot code in the NAND flash memory 60 is transmitted to the boot SRAM 20 and stored therein, and the CPU 70 reads the boot code and issues a command to transmit a system initialization code, an operating system (OS) code, or an application program code to the main memory 80.

Responding to the above command, the operating system code or the application program code in the NAND flash memory 60 is transmitted to the SRAM buffer 30 and stored therein, and in an operation of the CPU 70 the operating system code or application program code stored in the SRAM buffer 30 is transmitted to a code section of the main memory 80. Then, the CPU 70 accesses the operating system code or application program code stored in the code section of the main memory 80.

After system booting, a controlling method of reading and writing general data is performed in a similar way to the above, in which the general data is transmitted to and stored in the SRAM buffer 30 and in an operation of the CPU 70 the data stored in the SRAM buffer 30 is transmitted to a data section of the main memory 80. Then, the CPU 70 reads the data stored in the data section of the main memory 80.

The SRAM buffer 30 in a conventional NAND flash memory controlling apparatus has a capacity of 528 bytes (in the case of a small capacity device) or 2112 bytes (in the case of a large capacity device) which is the size of a page of the NAND flash memory, but, nowadays, to improve data transmission speed, an increased number of SRAM buffers are used to buffer several pages. For example, a double buffering method having two or four 528-byte/2112-byte SRAM buffers is employed.

However, if a large capacity buffer is included in the NAND flash memory in order to improve speed of the NAND flash memory, managing the buffer is complicated, thus increasing the complexity of data transmission controlling. Furthermore, as the size of the buffer is increased, a memory chip size increases, which makes it difficult to realize a system on chip (SoC).

Moreover, according to the prior art, during system booting, since the OS code or application program code passes through the SRAM buffer and is transmitted to the main memory (SDRAM) in an operation of the CPU, it takes more time to boot. Booting processes are divided into roughly a system initialization step and an OS/application program code loading step, and most of the time is spent on loading the OS/application program code. Therefore, if an image is loaded using a buffering method of the prior art, longer boot time is required since data passes through a buffer and then is copied to a main memory.

### SUMMARY OF THE INVENTION

An aspect of the present invention provides an apparatus and method for controlling a NAND flash memory using a direct memory access (DMA) method, wherein the apparatus and method are capable of increasing data transmission speed, and reducing both memory chip size and the time required to boot a system.

According to another aspect of the present invention, there is provided a NAND flash memory controlling apparatus for controlling data transmission between a central processing unit and a NAND flash memory, the apparatus including a register storing an operating command from the central processing unit and information related to the operating command; a boot memory storing a boot code for initializing a system; a direct memory access (DMA) controller transmitting data stored in the NAND flash memory to a main memory without passing through the central processing unit; and a state machine controlling the NAND flash memory controlling apparatus.

According to another aspect of the present invention, the NAND flash memory controlling apparatus may further include an error correction code (ECC) circuit detecting and correcting a physical error of the NAND flash memory.

According to another aspect of the present invention, the DMA controller may include a first internal memory that receives the data from the NAND flash memory and transmits the data to the main memory in response to a control signal of the state machine.

According to another aspect of the present invention, the first internal memory may be a first-in first-out (FIFO) memory.

According to another aspect of the present invention, the NAND flash memory controlling apparatus may further include a counter adding or deleting data to/from the FIFO memory, a system address counter counting an address of the main memory, and a register storing information including the operating command from the central processing unit.

According to another aspect of the present invention, the boot code may include command codes for initializing a system or transmitting one of an operating system and/or an application program to the main memory.

According to another aspect of the present invention, the boot memory may be a static random access memory (SRAM).

According to another aspect of the present invention, the NAND flash memory controlling apparatus may further include a second internal memory which stores data transmitted from the NAND flash memory such that the data from the NAND flash memory is transmitted to the central processing unit without passing through the DMA controller.

According to another aspect of the present invention, the second internal memory may be a FIFO memory.

According to another aspect of the present invention, a data transmission path may be selectively set by the register.

According to another aspect of the present invention, there is provided a method of controlling data transmission between a central processing unit and a NAND flash memory, the method including: transmitting a boot code for initializing a system from the NAND flash memory to the central processing unit through a boot memory; requesting reading data from the NAND flash memory; transmitting the data from the NAND flash memory to a main memory without passing through the central processing unit according to the request; and the central processing unit reading the data transmitted to the main memory.

According to another aspect of the present invention, the transmission of the data may include receiving the data from the NAND flash memory and storing the data in a first internal memory to transmit the data to the main memory, and transmitting the data stored in the first internal memory to the main memory.

According to another aspect of the present invention, the first internal memory may be a FIFO memory.

According to another aspect of the present invention, the data may be one of an operating system and an application program.

According to still another aspect of the present invention, there is a method of controlling data transmission between a central processing unit and a NAND flash memory, the method including: transmitting a boot code for initializing a system from the NAND flash memory to the central processing unit through a boot memory; requesting reading data from the NAND flash memory; selectively setting a data transmission path according to whether or not a DMA controller for transmitting the data from the NAND flash memory to the main memory without passing through the central processing unit is used; and transmitting the data along the set data transmission path.

According to another aspect of the present invention, when the DMA controller is used, the transmission of the data may include: receiving the data from the NAND flash memory and storing the data in a first internal memory to transmit the data to the main memory; transmitting the data stored in the first internal memory to the main memory; and the central processing unit reading the data transmitted to the main memory.

According to another aspect of the present invention, the first internal memory may be a FIFO memory.

According to another aspect of the present invention, when the DMA controller is not used, the transmission of the data may include: storing the data from the NAND flash memory in a second internal memory; and the central processing unit reading the data stored in the second internal memory.

According to another aspect of the present invention, the second internal memory may be a FIFO memory.

Additional aspects and/or advantages of the invention will be set forth in part in the description which follows and, in part, will be obvious from the description, or may be learned by practice of the invention.

### BRIEF DESCRIPTION OF THE DRAWINGS

These and/or other aspects and advantages of the invention will become apparent and more readily appreciated from the following description of the embodiments, taken in conjunction with the accompanying drawings of which:

FIG. 1 is a block diagram schematically illustrating an apparatus for controlling a NAND flash memory according to the prior art;

FIG. 2 is a block diagram schematically illustrating an apparatus for controlling a NAND flash memory according to an embodiment of the present invention;

FIG. 3A illustrates a data structure of the NAND flash memory shown in FIG. 2;

FIG. 3B illustrates a data structure of a main memory illustrated in FIG. 2;

FIG. 3C schematically illustrates a structure of a register illustrated in FIG. 2;

FIG. 4 schematically illustrates a structure of a DMA controller illustrated in FIG. 2;

FIG. 5 is a flowchart illustrating a method of controlling a NAND flash memory according to an embodiment of the present invention; and

FIG. 6 is a flowchart illustrating a method of controlling a NAND flash memory according to another embodiment of the present invention.

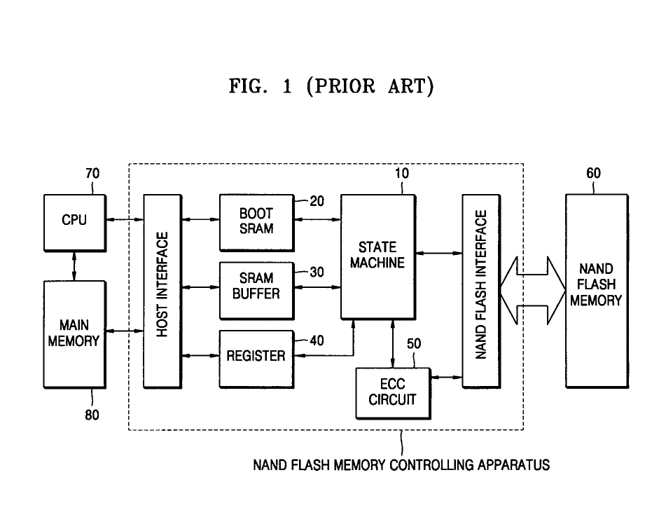

### DETAILED DESCRIPTION OF THE EMBODIMENTS

Reference will now be made in detail to the present embodiments of the present invention, examples of which are illustrated in the accompanying drawings, wherein like reference numerals refer to the like elements throughout. The embodiments are described below in order to explain the present invention by referring to the figures.

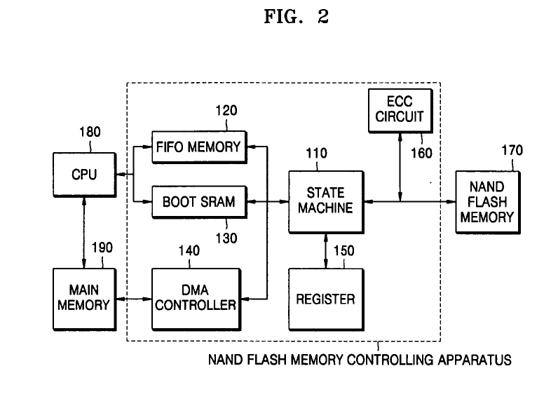

FIG. 2 is a block diagram schematically illustrating an apparatus for controlling a NAND flash memory according to an embodiment of the present invention. Referring to FIG. 2, the apparatus for controlling a NAND flash memory includes a state machine 110, a first-in first-out (FIFO) memory 120, a boot static random access memory (SRAM) 130, a direct memory access (DMA) controller 140, a register 150, and an error correction code (ECC) circuit 160. The apparatus for controlling a NAND flash memory interfaces with a NAND flash memory 170, a central processing unit (CPU) 180, and a main memory 190.

The state machine 110 controls operations throughout the apparatus, and in particular controls the DMA controller 140, and sets a data transmission path.

The state machine 110 selectively sets a data transmission path, and data is transmitted along the data transmission path. In the present embodiment, two data transmission paths are set, one of which is for transmitting data to the main memory 190 through the DMA controller 140 which will be described later and the other which is for transmitting data to the FIFO memory 120.

The FIFO memory 120 receives data from the NAND flash memory 170 and stores the data when the state machine 110 has set the data transmission path such that the CPU 180 directly accesses the data. The boot SRAM 130 stores a boot code. The boot code stored in the NAND flash memory 170 is transmitted to and stored in the boot SRAM 130 when a system is booted by turning on the system power. The CPU 180 reads the boot code stored in the boot SRAM 130, recognizes a command code included in the boot code, and issues an operating command.

Although an SRAM is used as the boot memory for storing the boot code in the present embodiment, the boot memory is not limited to the SRAM. The boot code includes command codes to initialize a system and transmit an operating system or an application program to the main memory.

When the CPU 180 recognizes such command codes, the CPU issues operating commands to perform operations of the command codes, for example, a command to initialize a peripheral device for system booting and transmit an operating system or an application program to the main memory 190.

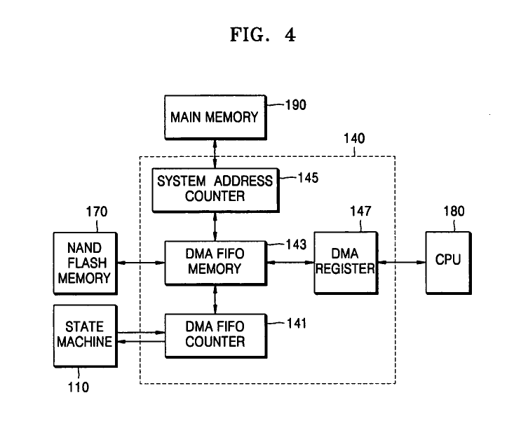

In response to the above command, the DMA controller 140 directly transmits data stored in the NAND flash memory 170 to the main memory 190 without passing through the CPU 180. The structure and functions of the DMA controller 140 will be described later in detail with reference to FIG. 4.

The register 150 is a storage area for reading operating commands from the CPU 180, storing information related to the operating commands and current status of the register 150 (ready/busy), and storing an address and the sizes of transmission data.

The ECC circuit 160 detects physical errors such as bad blocks of the NAND flash memory 170, and corrects the errors such that the CPU 180 cannot recognize incorrect data read from the bad blocks.

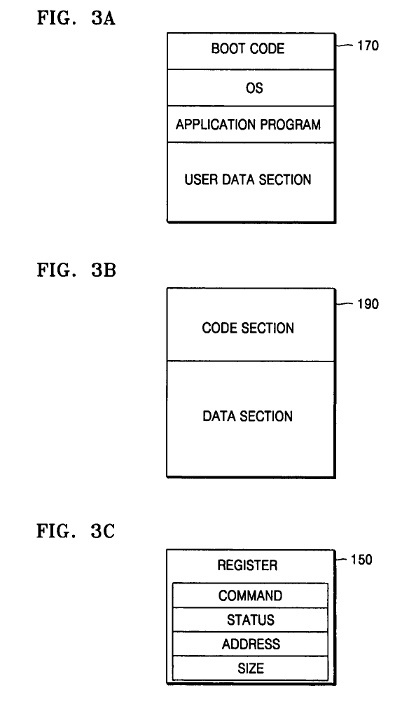

FIG. 3A illustrates a data structure of the NAND flash memory 170. The NAND flash memory includes a boot code, an operating system (OS), various application programs, and user data by sections.

FIG. 3B illustrates a data structure of the main memory 190, which is divided into a code section and a data section. The operating system and the application programs are transmitted to and stored in the code section, and the user data is transmitted to and stored in the data section.

FIG. 3C schematically illustrates a structure of the register 150, in which the operating commands, the information related to the operating commands and the current status, and the address and the sizes of transmission data are stored.

The structure of the DMA controller 140 will be described with reference to FIG. 4. The DMA controller 140 includes a DMA FIFO counter 141, a DMA FIFO memory 143, a system address counter 145, and a DMA register 147.

The DMA controller 140 stores the data transmitted from the NAND flash memory 170 in the DMA FIFO memory 143, and transmits the stored data to the main memory 190 in response to a control signal of the state machine 110. Although the FIFO memory 120 is used to store the data in the present embodiment, the memory is not limited to the FIFO memory 120.

The DMA FIFO counter 141 counts changes in data of the FIFO memory 120, the system address counter 145 counts the address of the main memory 190, and the DMA register 147 stores the operating command, status information and the address received from the CPU 180. A

When the data stored in the NAND flash memory 170 is transmitted to the main memory 190 by using the DMA controller 140, the CPU 180 issues only one such transmission command and can perform another operation. Furthermore, the time required for data transmission and storing to buffer memory is saved, and thus the data transmission time is reduced.

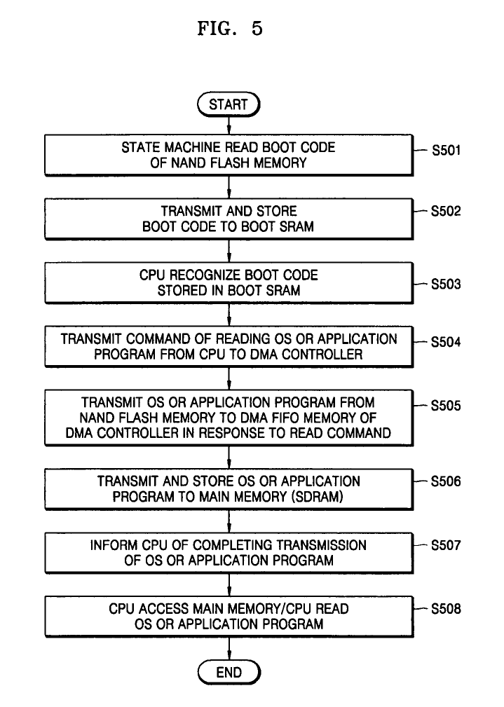

FIG. 5 is a flowchart illustrating a method of controlling the NAND flash memory 170 according to an embodiment of the present invention. The flowchart of FIG. 5 illustrates procedures for initializing an operating system or application programs stored in the NAND flash memory 170 while a system is initialized.

Referring to FIG. 5, when a system power is turned on, the state machine 110 of the NAND flash memory controlling apparatus reads a boot code stored in the NAND flash memory 170 (S501). As described above, the boot code includes such command codes as a command to initialize the system, and a command to transmit an operating system (OS) or application program to the main memory 190.

The boot code is transmitted to and stored in the boot SRAM 130 (S502).

The CPU 180 recognizes the boot code stored in the boot SRAM 130 (S503).

According to the boot code, the CPU 180 transmits a reading command of the operating system or the application program to the DMA controller 140 (S504).

In response to the command, the operating system or the application program is transmitted from the NAND flash memory 170 to the DMA FIFO memory 143 of the DMA controller 140 (S505).

Then, the operating system or the application program transmitted to the DMA FIFO memory 143 is transmitted to and stored in the main memory 190 (S506). Although the SDRAM is used as the main memory in the present embodiment, the main memory is not limited to the SDRAM.

When the operating system or the application program is completely transmitted to the main memory 190, an interrupt is generated so that the CPU 180 is informed that the transmission is complete (S507).

The CPU 180 accesses the main memory 190 and reads the operating system or the application program stored in the main memory 190 (S508).

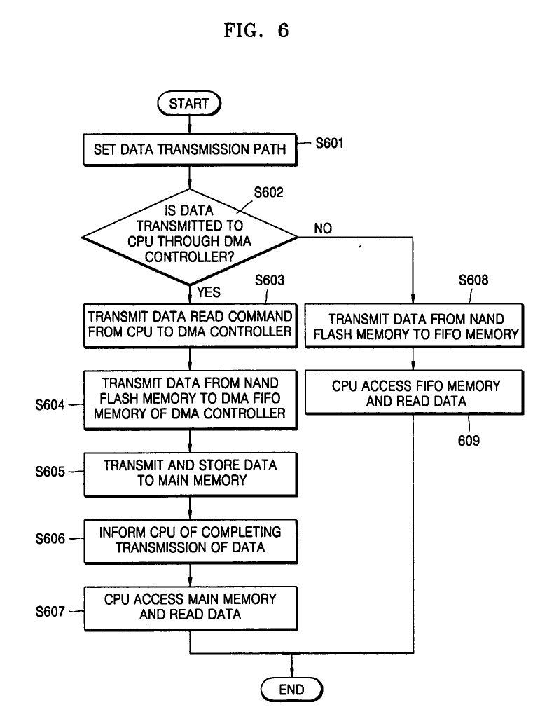

FIG. 6 is a flowchart illustrating a method of controlling the NAND flash memory 170 according to another embodiment of the present invention. The flowchart of FIG. 6 illustrates procedures for transmitting general user data between the NAND flash memory 170 and the CPU 180 after the system is initialized.

Referring to FIG. 6, the state machine 110 sets a data transmission path (S601).

The data transmission path set in operation S601 (S602) is determined, that is, whether the data is transmitted to the CPU 180 via the DMA controller 140 or not.

If the data transmission path is set such that the data is transmitted to the CPU 180 via the main memory 190, the CPU 180 transmits a data reading command to the DMA controller 140 (S603).

Then, the data is transmitted from the NAND flash memory 170 to the DMA FIFO memory 143 of the DMA controller 140 (S604).

The data stored in the DMA FIFO memory 143 is transmitted to and stored in the main memory 190 (S605).

When the data transmission to the main memory 190 is complete, an interrupt is generated so that the CPU 180 is informed that the transmission is complete (S606).

The CPU 180 accesses the main memory 190, and reads the data (S607).

Returning to operation S602, if the data transmission path is set such that the data is directly transmitted to the CPU 180 without passing through the main memory 190, the data is transmitted from the NAND flash memory 170 to the FIFO memory 120 of the NAND flash memory controlling apparatus (S608).

The CPU 180 accesses the FIFO memory 120, and reads the data (S609). Although a data reading procedure has been chiefly described in the present embodiment, a person having ordinary skill in the art can understand that a data writing procedure is performed similar to the data reading procedure.

As described above, according to an embodiment of the present invention, since a DMA controller is used instead of a buffer memory, space occupied by the buffer memory is reduced, and thus the size of a memory chip decreases.

Furthermore, because data is directly transmitted from a NAND flash memory to a main memory without passing through a CPU, data transmission speed increases, the time required to boot is reduced, and the CPU can perform other operations, resulting in an improved performance of the entire system.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A NAND flash memory controlling apparatus for controlling data transmission between a central processing unit (CPU) and a NAND flash memory, the apparatus comprising:
a register storing an operating command from the central processing unit and information related to the operating command;
a boot memory storing a boot code for initializing a system;
a direct memory access (DMA) controller transmitting data stored in the NAND flash memory to a main memory without passing through the central processing unit; and
a state machine controlling the NAND flash memory controlling apparatus.

2. The apparatus of claim 1, further comprising:
an error correction code (ECC) circuit detecting and correcting a physical error of the NAND flash memory.

3. The apparatus of claim 1, wherein the DMA controller comprises a first internal memory that receives the data from the NAND flash memory and transmits the data to the main memory in response to a control signal of the state machine.

4. The apparatus of claim 3, wherein the first internal memory is a first-in first-out (FIFO) memory.

5. The apparatus of claim 4, further comprising:
a counter adding or deleting data to/from the FIFO memory;
a system address counter counting an address of the main memory; and
a register storing information comprising the operating command from the central processing unit.

6. The apparatus of claim 1, wherein the boot code comprises command codes for initializing the system or transmitting one of an operating system and/or an application program to the main memory.

7. The apparatus of claim 6, wherein the boot memory is a static random access memory (SRAM).

8. The apparatus of claim 1, further comprising:
a second internal memory which stores data transmitted from the NAND flash memory such that the data from the NAND flash memory is transmitted to the central processing unit without passing through the DMA controller.

9. The apparatus of claim 8, wherein the second internal memory is a FIFO memory.

10. The apparatus of claim 8, wherein a data transmission path is selectively set by the register.

11. A method of controlling data transmission between a central processing unit and a NAND flash memory, the method comprising:
transmitting a boot code for initializing a system from the NAND flash memory to the central processing unit through a boot memory;
requesting data from the NAND flash memory;
transmitting the data from the NAND flash memory to a main memory without passing through the central processing unit according to the request; and
reading the data transmitted to the main memory.

12. The method of claim 11, wherein the transmission of the data comprises:
receiving the data from the NAND flash memory and storing the data in a first internal memory to transmit the data to the main memory; and
transmitting the data stored in the first internal memory to the main memory.

13. The method of claim 12, wherein the first internal memory is a FIFO memory.

14. The method of claim 13, wherein the data is one of an operating system and an application program.

15. A method of controlling data transmission between a central processing unit and a NAND flash memory, the method comprising:
transmitting a boot code for initializing a system from the NAND flash memory to the central processing unit through a boot memory;
requesting data from the NAND flash memory;
selectively setting a data transmission path, according to whether or not a DMA controller is used, for transmitting the data from the NAND flash memory to a main memory without passing through the central processing unit; and
transmitting the data along the set data transmission path.

16. The method of claim 15, wherein, when the DMA controller is used, the transmission of the data comprises:
receiving the data from the NAND flash memory and storing the data in a first internal memory to transmit the data to the main memory;
transmitting the data stored in the first internal memory to the main memory; and
reading the data transmitted to the main memory.

17. The method of claim 16, wherein the first internal memory is a FIFO memory.

18. The method of claim 15, wherein, when the DMA controller is not used, the transmission of the data comprises:
storing the data from the NAND flash memory in a second internal memory; and
reading the data stored in the second internal memory.

19. The method of claim 18, wherein the second internal memory is a FIFO memory.

20. The apparatus of claim 4, wherein a first transmission path transmits data to the main memory through the DMA controller and a second transmission path transmits data to the FIFO memory.

21. The apparatus of claim 4, wherein the FIFO memory receives data from the NAND flash memory and stores the data when the state machine has set the data transmission path such that the CPU directly accesses the data.

22. A NAND flash memory controlling apparatus controlling data transmission between a central processing unit (CPU), a NAND flash memory and a main memory, the apparatus comprising:
a state machine setting at least one data transmission path;
a first-in first-out (FIFO) memory receiving data from the NAND flash memory and storing the data when the state machine has set the data transmission path such that the CPU directly accesses the data; and
a direct memory access (DMA) controller, directly transmitting the data stored in the NAND flash memory to the main memory without passing through the CPU when the state machine has set the data transmission path such that the main memory directly accesses the data.

23. The apparatus of claim 22, further comprising a boot static random access memory (SRAM) storing a boot code stored in the NAND flash memory and transmitted to the boot SRAM when a system is booted.

24. The apparatus of claim 23, wherein the CPU reads the boot code stored in the boot SRAM, recognizes a command code included in the boot code, and issues an operating command.

25. The apparatus of claim 23, wherein the boot code includes command codes to initialize the system.

26. The apparatus of claim 22, wherein the NAND flash memory includes a boot code, an operating system, application programs and user data.

27. The apparatus of claim 22, wherein the main memory includes a code section and a data section.

28. The apparatus of claim 27, wherein the code section includes an operating system and application programs and the data section includes user data.

29. A method of controlling data transmission between a central processing unit and a NAND flash memory, the method comprising:
transmitting a boot code for initializing a system from the NAND flash memory to the central processing unit through a boot memory;
requesting data from a main memory;
selectively setting a data transmission path, according to whether or not a DMA controller is used, for transmitting the data from the main memory to the NAND flash memory without passing through the central processing unit; and
transmitting the data along the set data transmission path.
